(19) United States
(12) Patent Application Publication
(10) Pub. No.: US 2025/0133159 A1
(43) Pub. Date: Apr. 24, 2025

(54) ELECTRONIC DEVICE INCLUDING EXTERNAL FRAME

(71) Applicant: Samsung Electronics Co., Ltd., Suwon-si (KR)

(72) Inventors: Jaewoong CHUNG, Suwon-si (KR); Junghyuck IM, Suwon-si (KR)

(21) Appl. No.: 18/799,584

(22) Filed: Aug. 9, 2024

Related U.S. Application Data
(63) Continuation of application No. PCT/KR2024/010066, filed on Jul. 12, 2024.

(30) Foreign Application Priority Data
Oct. 20, 2023 (KR) 10-2023-0141573
Dec. 6, 2023 (KR) 10-2023-0175848

(51) Int. Cl. H04M 1/02; H05K 1/02; H05K 5/02

(52) U.S. Cl. CPC H04M 1/0268; H05K 1/0277; H05K 5/0217

(57) ABSTRACT

An electronic device is disclosed. The electronic device includes: a first housing, a second housing configured to be movably coupled to the first housing, a flexible display configured to change a visible area according to the movement of the second housing, and an external frame connected to the portion of the first housing and configured to protect the bending portion of the flexible display from external impact.

### CROSS-REFERENCE TO RELATED APPLICATIONS

This application is a continuation of International Application No. PCT/KR2024/010066 designating the United States, filed on Jul. 12, 2024, in the Korean Intellectual Property Receiving Office and claiming priority to Korean Patent Application Nos. 10-2023-0141573, filed on Oct. 20, 2023, and 10-2023-0175848, filed on Dec. 6, 2023, in the Korean Intellectual Property Office, the disclosures of each of which are incorporated by reference herein in their entireties.

### BACKGROUND

### Field

The disclosure relates to an electronic device including an external frame.

### Description of Related Art

In order to increase portability and usability of an electronic device, an electronic device including a flexible display capable of providing a large screen display when necessary is being developed. Since the flexible display may be vulnerable to external impact. As the flexible device may be rolled up into a housing, a mounting space of an electronic component may be insufficient.

The above-described information may be provided as a related art for the purpose of helping to understand the present disclosure. No claim or determination is raised as to whether any of the above-described information can be applied as a prior art related to the present disclosure.

### SUMMARY

According to an example embodiment, an electronic device may include: a first housing, a second housing configured to be movably coupled to the first housing, a flexible display configured to move to change a visible area according to a movement of the second housing, and an external frame coupled to a portion of the first housing and configured to protect a bending portion of the flexible display from external impact.

According to an example embodiment, an electronic device may include: a first housing, a second housing configured to be movably coupled to the first housing, a flexible display disposed at least partially within the first housing and configured to be partially rolled into the first housing, and an external frame including connection portions connected to both side surfaces of a portion of the first housing into which the flexible display is rolled and a frame part disposed between the connection portions and spaced apart from the portion of the first housing, wherein the external frame may at least partially surround a surface of the first housing facing the frame part and is configured to protect a bending portion of the flexible display from impact applied to the frame part.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1A is a diagram illustrating a top plan view of an example electronic device in a first state according to various embodiments;

FIG. 1B is a diagram illustrating a bottom view of an example electronic device in a first

state according to various embodiments;

FIG. 1C is a diagram illustrating a top plan view of an example electronic device in a second state according to various embodiments;

FIG. 1D is a diagram illustrating a bottom view of an example electronic device in the second state according to various embodiments;

FIGS. 2A and 2B are exploded perspective views of an example electronic device according to various embodiments;

FIG. 3A is a cross-sectional view of an example electronic device in a first state according to various embodiments;

FIG. 3B is a cross-sectional view of an example electronic device in a second state according to various embodiments;

FIG. 4 is a diagram illustrating a top plan view of an example electronic device including an external frame according to various embodiments;

FIG. 5 is a partial cross-sectional view of an example electronic device including an external frame according to various embodiments;

FIG. 6 is a perspective view illustrating an example electronic device including an external frame acting as an antenna radiator according to various embodiments;

FIG. 7 is an exploded perspective view of an example electronic device including an external frame acting as an antenna radiator according to various embodiments;

FIG. 8A is a perspective view illustrating an external frame acting as an antenna radiator according to various embodiments;

FIG. 8B is a perspective view illustrating an external frame including a conductive portion acting as a segmented antenna radiator according to various embodiments;

FIG. 8C is a perspective view illustrating an external frame including a conductive portion acting as an antenna radiator providing multiple bands according to various embodiments;

FIG. 9 is a perspective view of an example electronic device including a rotatable external frame according to various embodiments;

FIG. 10 is a perspective view illustrating an interior of an example electronic device including a rotatable external frame according to various embodiments;

FIG. 11A is a diagram illustrating a connection relationship between a terminal and a conductive portion according to a rotation of an external frame according to various embodiments;

FIG. 11B is a perspective view illustrating an external frame including a contact for maintaining contact with a terminal while rotating according to various embodiments;

FIG. 12 is a perspective view of an example electronic device including an external frame to which an accessory may be fastened according to various embodiments; and

FIG. 13 is a block diagram illustrating an example electronic device in a network environment according to various embodiments.

### DETAILED DESCRIPTION

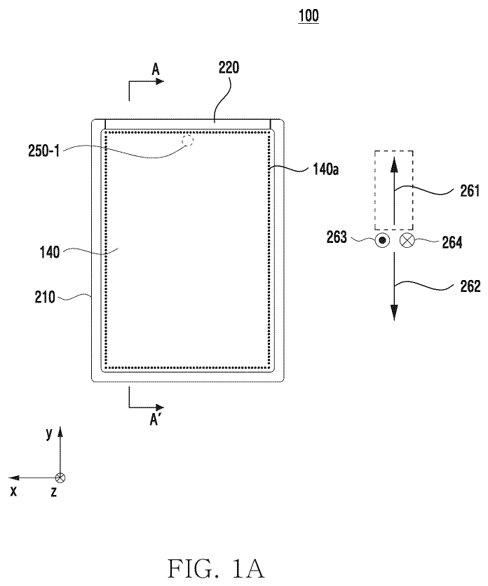

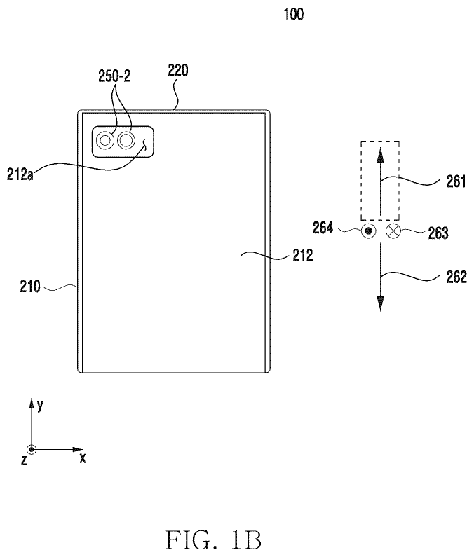

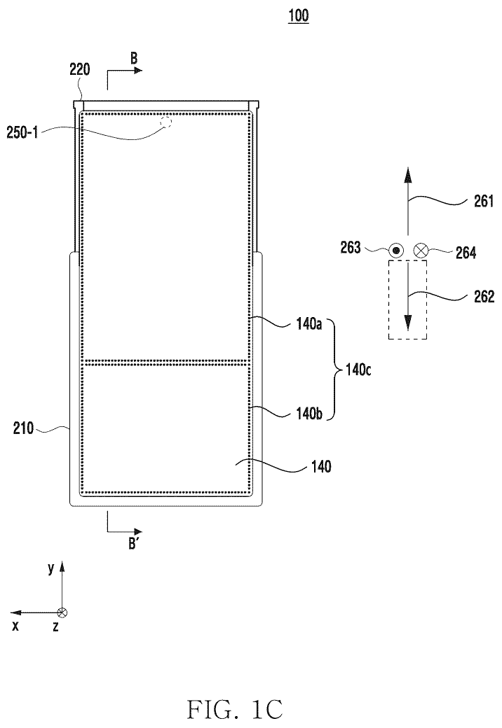

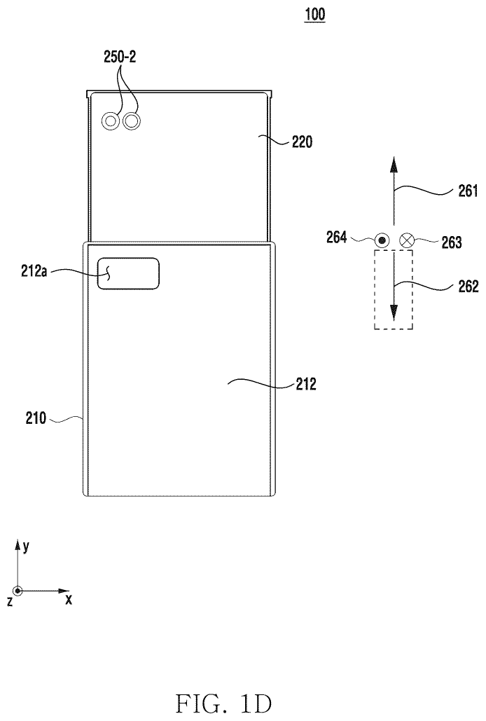

FIG. 1A is a diagram illustrating a top plan view of an example electronic device 100 in a first state according to various embodiments.

Referring to FIG. 1A, an electronic device 100 may include a first housing 210, a second housing 220 that is movable with respect to the first housing 210 in a first direction 261 parallel to the y-axis or a second direction 262 parallel to the y-axis and opposite to the first direction 261, and a display 140. Since the first housing 210 and the second housing 220 are coupled to form an exterior of the electronic device, they may be referred to as a housing. Considering that each of the first housing 210 and the second housing 220 is a component configuring the housing, it may be referred to as a first housing part and a second housing part.

For example, in the first state, the second housing 220 may be movable with respect to the first housing 210 in the first direction 261 of the first direction 261 and the second direction 262. For example, in the first state, the second housing 220 may not be movable with respect to the first housing 210 in the second direction 262. Although the present disclosure describes that the second housing 220 moves with respect to the first housing 210, it may be interpreted that the first housing 210 moves with respect to the second housing 220.

For example, in the first state, the display 140 may provide the display area having the smallest size. For example, in the first state, the display area may correspond to a first area 140a. For example, although not shown in FIG. 1A, in the first state, an area (e.g., a second area 140b of FIG. 1C) of the display 140 different from the first area 140a, which is the display area, may be disposed in the first housing 210. For example, in the first state, the second area 140b may be covered by the first housing 210. For example, in the first state, the second area 140b may be moved into the first housing 210. For example, at least a portion of the second area 140b may be rolled into the first housing 210. For example, in the first state, the first area 140a may include a planar portion. For example, in the first state, a portion of the second area 140b may include a curved portion. However, the disclosure is not limited thereto. For example, the first area 140a may include a curved portion extending from the planar portion.

For example, the first state may be referred to as a slide-in state in terms of at least a portion of the second housing 220 being located within the first housing 210 according to the second housing 220 slid toward the first housing 210. For example, the first state may be referred to as a reduced state in terms of providing the display area having the smallest size. However, the disclosure is not limited thereto.

For example, the first housing 210 may include a front camera 250-1 obtaining visual information through a portion of the first area 140a and facing a third direction 263 parallel to the z-axis. For example, although not shown in FIG. 1A, the second housing 220 may include one or more rear cameras (e.g., rear cameras 250-2 of FIG. 1B) visually exposed through a portion of the second housing 220 and facing in a fourth direction 264 parallel to the z-axis and opposite to the third direction 263. For example, the one or more rear cameras 250-2 may be illustrated and described in greater detail below through a description of FIG. 1B.

FIG. 1B is a diagram illustrating a bottom view of an example electronic device in a first state according to various embodiments.

Referring to FIG. 1B, in the first state, one or more rear cameras 250-2 disposed in a second housing 220 may be located within a structure disposed in a first housing 210 for the one or more rear cameras 250-2. For example, since the one or more rear cameras 250-2 are located within the structure in the first state, the one or more rear cameras 250-2 may be visually exposed through the structure in the first state. The one or more rear cameras 250-2 may obtain visual information through the structure. For example, the structure may be implemented in various ways. For example, the structure may be an opening or a notch. For example, the structure may be an opening 212a in a first plate 212 of the first housing 210 surrounding at least a portion of the second housing 220. However, the disclosure is not limited thereto.

The first state may be changed to the second state. For example, the first state (or the second state) may be changed to the second state (or the first state) through one or more intermediate states between the first state and the second state.

For example, the first state (or the second state) may be changed to the second state (or the first state) based on an input, e.g., a defined user input. For example, the first state (or the second state) may be changed to the second state (or the first state) in response to a user input to a physical button visually exposed through a portion of the first housing 210 or a portion of the second housing 220. There is no limitation on a type of the user input. For example, the user input may include a user input through a touch screen in a display area of a display 140 or a user input through a microphone of an electronic device 100. For example, a state of the electronic device 100 may be changed to the second state (or the first state) by an external force applied to the first housing 210 and/or the second housing 220.

The second state may be illustrated and described in greater detail below through descriptions of FIGS. IC and 1D.

FIG. 1C is a diagram illustrating a top plan view of an example electronic device in a second state according to various embodiments.

Referring to FIG. 1C, in the second state, a second housing 220 may be movable with respect to a first housing 210 in a second direction 262 of a first direction 261 and the second direction 262. For example, in the second state, the second housing 220 may not be movable with respect to the first housing 210 in the first direction 261.

For example, in the second state, the display 140 may provide the display area having the largest size. For example, in the second state, the display area may correspond to an area 140C including a first area 140a and a second area 140b. For example, the second area 140b, which was included in the first housing 210 in the first state, may be visually exposed in the second state. For example, in the second state, the first area 140a and the second area 140b may include a planar portion. However, the disclosure is not limited thereto. For example, the first area 140a and/or the second area 140b may include a curved portion extending from the planar portion and located within an edge portion.

For example, the second state may be referred to as a slide-out state in terms of at least a portion of the second housing 220 being located outside the first housing 210 according to the second housing 220 slid from the first housing 210. For example, the second state may be referred to as an extended state in terms of providing the display area having the largest size. However, the disclosure is not limited thereto.

For example, when a state of the electronic device 100 changes from the first state to the second state, a front camera 250-1 facing a third direction 263 may move together with the first area 140a, according to a movement of the second housing 220 in the first direction 261. For example, although not shown in FIG. 1C, one or more rear cameras (e.g., rear cameras 250-2 of FIG. 1D) facing a fourth direction 264 may move together with the second housing 220 according to the movement of the second housing 220 in the first direction 261, when the state of the electronic device 100 changes from the first state to the second state. For example, a relative positional relationship between one or more rear cameras 250-2 and the structure illustrated and described through the description of FIG. 1B may be changed according to the movement of one or more rear cameras 250-2. For example, the change of the relative positional relationship may be illustrated and described in greater detail below through FIG. 1D.

FIG. 1D is a diagram illustrating a bottom view of an example electronic device in a second state according to various embodiments.

Referring to FIG. 1D, in the second state, one or more rear cameras 250-2 may be located outside the structure. For example, in the second state, the one or more rear cameras 250-2 may be located outside an opening 212a in a first plate 212. For example, since the one or more rear cameras 250-2 are located outside the opening 212a in the second state, the one or more rear cameras 250-2 may be visually exposed in the second state. The one or more rear cameras 250-2 located outside the structure may obtain visual information. For example, since the one or more rear cameras 250-2 are located outside the structure in the second state, the relative positional relationship between the one or more rear cameras 250-2 and the structure (e.g., the opening 212a) in the second state may be different from the relative positional relationship between the one or more rear cameras 250-2 and the structure (e.g., the opening 212a) in the first state (e.g., FIG. 1B)

Although not shown in FIGS. 1A, 1B, 1C, and 1D, the electronic device 100 may be in an intermediate state between the first state and the second state. For example, a size of the display area in the intermediate state may be larger than a size of the display area in the first state and smaller than a size of the display area in the second state. For example, the display area in the intermediate state may correspond to an area including a portion of the first area 140a and the second area 140b. For example, in the intermediate state, a portion of the second area 140b may be visually exposed, and another portion (or a remaining portion) of the second area 140b may be covered by the first housing 210 or moved into the first housing 210. However, the disclosure is not limited thereto.

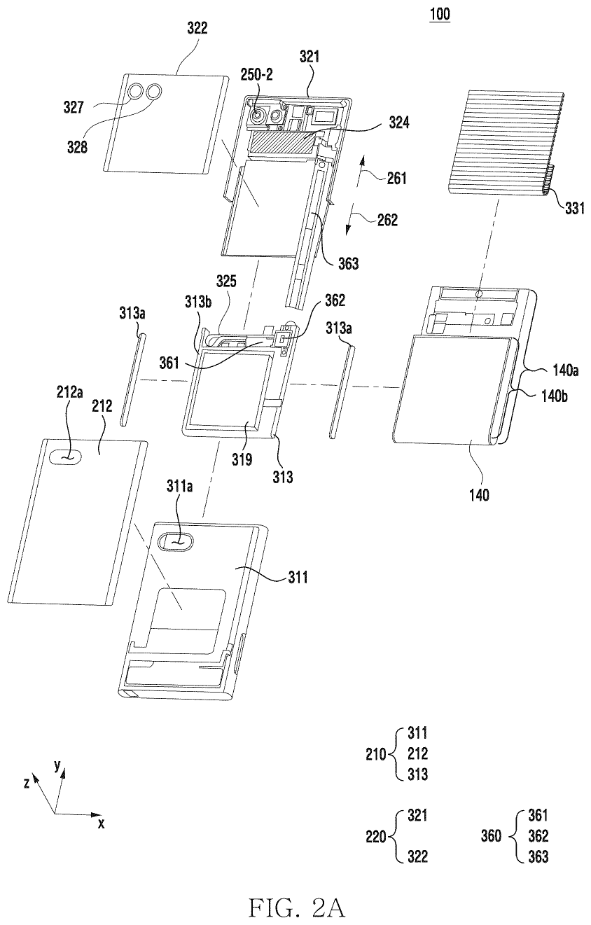

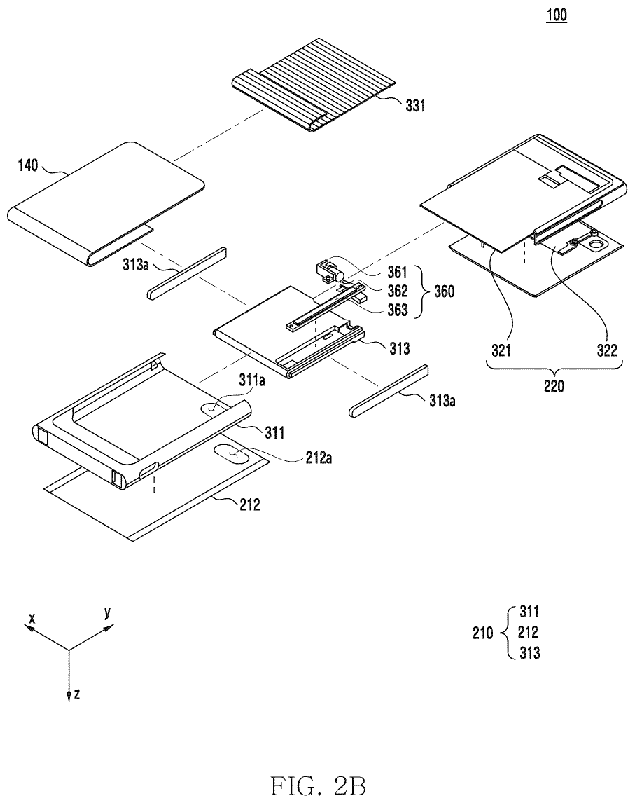

An electronic device 100 may include structures for moving a second housing (e.g., the second housing 220 of FIG. 1A, FIG. 1B, FIG. 1C, and FIG. 1D) of the electronic device 100 with respect to a first housing (e.g., the first housing 210 of FIG. 1A, FIG. 1B, FIG. 1C, and FIG. 1D) of the electronic device 100. For example, the structures may be illustrated and described in greater detail below through the descriptions of FIGS. 2A and 2B.

FIGS. 2A and 2B are exploded perspective views of an example electronic device according to various embodiments.

Referring to FIGS. 2A and 2B, an electronic device 100 may include a first housing 210, a second housing 220, a display 140, and a driving unit (e.g., including a motor and/or gear) 360.

For example, the first housing 210 may include a first cover 311, a first plate 212, and a frame 313.

For example, the first cover 311 may at least partially form a side surface portion of an outer surface of the electronic device 100. For example, the first cover 311 may at least partially form a rear surface portion of the outer surface. For example, the first cover 311 may include an opening 31 la for one or more rear cameras 250-2. For example, the first cover 311 may include a surface supporting the first plate 212. For example, the first cover 311 may be coupled to the first plate 212. For example, the first cover 311 may provide a space in which the frame 313 is seated. For example, the first cover 311 may be coupled to the frame 313.

For example, the first plate 212 may at least partially form a rear surface portion of the outer surface. For example, the first plate 212 may include an opening 212a for the one or more rear cameras 250-2. For example, the first plate 212 may be disposed on the surface of the first cover 311. For example, the opening 212a may be aligned with the opening 311a.

For example, the frame 313 may be at least partially surrounded by the first cover 311.

For example, the frame 313 may be at least partially surrounded by the display 140. For example, the frame 313 may be at least partially surrounded by the display 140, but a position of the frame 313 may be maintained independently of a movement of the display 140. For example, the frame 313 may be arranged with respect to at least a portion of components of the display 140. For example, the frame 313 may include rails 313a providing (or guiding) a path for a movement of at least one component of the display 140.

For example, the frame 313 may be coupled to at least one component of the electronic device 100. For example, the frame 313 may support a rechargeable battery 319. For example, the battery 319 may be supported through a recess or a hole in a surface 313b of the frame 313. For example, the frame 313 may fasten an end portion of a flexible printed circuit board 325 (FPCB) on a surface of the frame 313. The end portion of the FPCB 325 may be electrically connected to a motor 361. For example, although not explicitly shown in FIGS. 2A and 2B, another end portion of the FPCB 325 may be connected to a PCB 324 through at least one connector. For example, the PCB 324 may be electrically connected to another PCB (not shown in FIGS. 2A and 2B) supplying power to the motor 361 through the FPCB 325.

For example, the frame 313 may be coupled to at least one structure of the electronic device 100 for a plurality of states including the first state and the second state. For example, the frame 313 may fasten the motor 361 of the driving unit 360.

For example, the second housing 220 may be movably engaged with the first housing 210. The second housing 220 may include a second cover 321 and a second plate 322.

For example, the second cover 321 may be at least partially covered by the display 140. For example, the second cover 321, unlike the frame 313, may be coupled to at least a portion of a first area 140a of the display 140 surrounding the second cover 321, so that the display 140 is moved along the second housing 220 that is moved with respect to the first housing 210.

For example, the second cover 321 may be coupled to at least one component of the electronic device 100. For example, the second cover 321 may be coupled to a printed circuit board 324 (PCB) including components of the electronic device 100. For example, the PCB 324 may include a processor (not shown in FIGS. 2A and 2B). For example, the second cover 321 may include one or more rear cameras 250-2.

For example, the second cover 321 may be coupled to at least one structure of the electronic device 100 for a plurality of states including the first state and the second state. For example, the second cover 321 may fasten a rack gear 363 of the driving unit 360.

For example, the motor 361 of the driving unit 360 may be fastened to the second cover 321, and the rack gear 363 of the driving unit 360 may be fastened to the frame 313.

For example, the second cover 321 may be coupled to the second plate 322.

For example, the second plate 322 may be coupled to the second cover 321 to protect at least one component of the electronic device 100 coupled within the second cover 321 and/or at least one structure of the electronic device 100 coupled within the second cover 321. For example, the second plate 322 may include the structure for the at least one component. For example, the second plate 322 may include one or more openings 327 and 328 for the one or more rear cameras 250-2. For example, the one or more openings 327 and 328 may be aligned with the one or more rear cameras 250-2 disposed on the second cover 321. For example, a size of each of one or more openings 327 and 328 may correspond to a size of each of the one or more rear cameras 250-2.

For example, the display 140 may include a support member 331. The support member 331 may include a plurality of bars. The plurality of bars may be coupled to each other. The support member 331 may support a second area 140b of the display 140.

For example, the driving unit 360 may include the motor 361, a pinion gear 362, and the rack gear 363.

For example, the motor 361 may operate based on power from the battery 319. The power may be provided to the motor 361 in response to a defined user input.

For example, the pinion gear 362 may be coupled through the motor 361 and a shaft. For example, the pinion gear 362 may be rotated based on the operation of the motor 361 transmitted through the shaft.

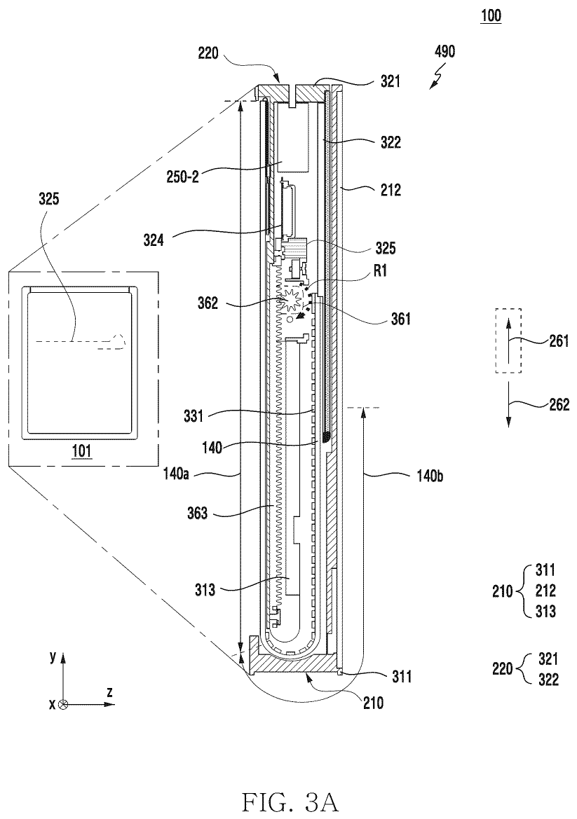

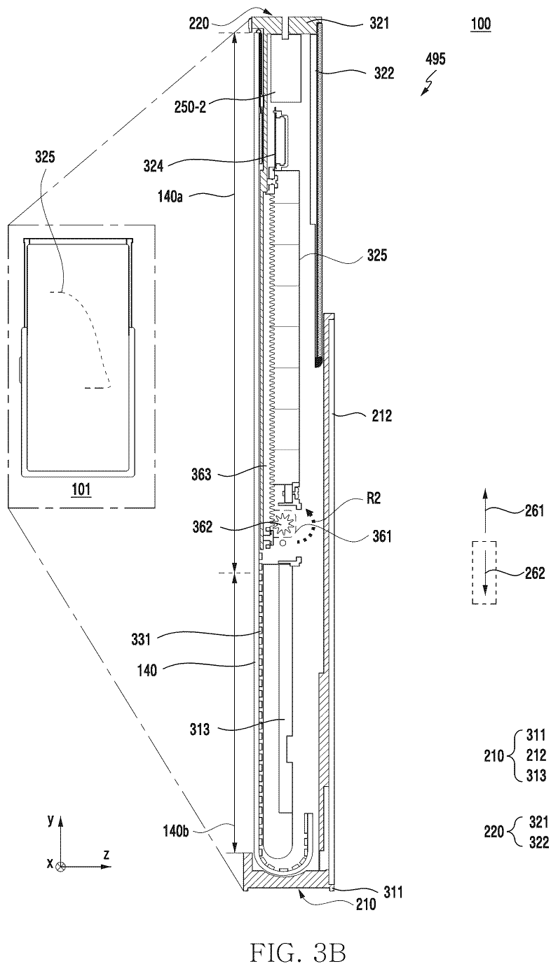

For example, the rack gear 363 may be arranged in relation to the pinion gear 362. For example, teeth of the rack gear 363 may be engaged with teeth of the pinion gear 362. For example, according to the rotation of the pinion gear 362, the rack gear 363 may be moved in a first direction 261 or a second direction 262. For example, the second housing 220 may be moved in the first direction 261 and the second direction 262, by the rack gear 363 moved according to the rotation of the pinion gear 362 due to the operation of the motor 361. For example, the first state of the electronic device 100 may be changed to a state (e.g., the one or more intermediate states or the second state) different from the first state, through the movement of the second housing 220 in the first direction 261. For example, the second state of the electronic device 100 may be changed to a state (e.g., the one or more intermediate states or the first state) different from the second state, through the movement of the second housing 220 in the second direction 262. For example, changing of the first state to the second state by the driving unit 360 and changing of the second state to the first state by the driving unit 360 may be illustrated and described in greater detail below through FIGS. 3A and 3B.

FIG. 3A is a cross-sectional view of an example electronic device in a first state according to various embodiments. FIG. 3B is a cross-sectional view of an example electronic device in a second state according to various embodiments.

Referring to FIGS. 3A and 3B, a motor 361 may be operated based at least in part on the defined user input received in the first state 490. For example, a pinion gear 362 may be rotated in a first rotation direction R1, based at least in part on the operation of the motor 361. For example, a rack gear 363 may be moved in a first direction 261 based at least in part on the rotation of the pinion gear 362 in the first rotation direction R1. For example, since a second cover 321 in a second housing 220 fastens the rack gear 363, the second housing 220 may be moved in the first direction 261 based at least in part on the movement of the rack gear 363 in the first direction 261. For example, since the second cover 321 in the second housing 220 is coupled to at least a portion of a first area 140a of the display 140 and fastens the rack gear 363, the display 140 may be moved in the first direction 261, based at least in part on the movement of the rack gear 363 in the first direction 261. For example, the display 140 may be moved along the rails 313a of FIG. 2B. For example, as a support member 331 is moved along the rails 313a in the first direction 261, the display 140 supported by the support member 331 may be moved in the first direction 261. For example, when the first state 490 is changed to the second state 495, a shape of at least a portion of the plurality of bars of the support member 331 of the display 140 may be changed.

For example, a second area 140b of the display 140 may be moved according to the movement of the display 140. For example, when the first state 490 is changed to the second state 495 according to the defined user input, the second area 140b may be moved through a space between a first cover 311 and a frame 313. For example, the second area 140b in the second state 495 may be visually exposed, unlike the second area 140b rolled into the space in the first state 490.

For example, since the second cover 321 in the second housing 220 is coupled to a PCB 324 connected to the other end of a FPCB 325 and fastens the rack gear 363, a shape of the FPCB 325 may be changed when the first state 490 is changed to the second state 495.

The motor 361 may be operated based at least in part on the defined user input received in the second state 495. For example, the pinion gear 362 may be rotated in a second rotation direction R2, based at least in part on the operation of the motor 361. For example, the rack gear 363 may be moved in the second direction 262, based at least in part on the rotation of the pinion gear 362 in the second rotation direction R2. For example, since the second cover 321 in the second housing 220 fastens the rack gear 363, the second housing 220 may be moved in the second direction 262 based at least in part on the movement of the rack gear 363 in the second direction 262. For example, since the second cover 321 in the second housing 220 is coupled to at least a portion of the first area 140a of the display 140 and fastens the rack gear 363, the display 140 may be moved based at least in part on the movement of the rack gear 363 in the second direction 262. As the support member 331 is moved along the rails 313a in the second direction 262, the display 140 supported by the support member 331 may be moved in the second direction 262. For example, the display 140 may be moved along rails (e.g., the rails 313a of FIG. 2B). For example, a shape of at least a portion of the plurality of the bars of the support member 331 of the display 140 may be changed, when the second state 495 is changed to the first state 490. The support member 331 may be moved with respect to a first housing 210. The support member 331 stored inside the first housing 210 in the first state 490 may be located between the first cover 311 and the frame 313. The display 140 may be moved with respect to the first housing 210 according to the movement of the support member 331.

For example, the second area 140b of the display 140 may be moved according to the movement of the display 140. For example, when the second state 495 is changed to the first state 490 according to the defined user input, the second area 140b may be moved through the space between the first cover 311 and the frame 313. For example, the second area 140b in the first state 490 may be rolled into the space, unlike the second area 140b visually exposed in the second state 495.

For example, since the second cover 321 in the second housing 220 is coupled to the PCB 324 connected to the other end of the FPCB 325 and fastens the rack gear 363, a shape of the FPCB 325 may be changed, when the second state 495 is changed to the first state 490.

FIGS. 1A, 1B, 1C, 1D, 2A, 2B, 3A and 3B (which may be referred to as FIGS. 1A to 3B) illustrate the electronic device 100 in which a height of the display area is changed and a width of the display area is maintained when the first state (or the second state) is changed to the second state (or the first state) in a portrait mode, but it is for convenience of explanation. For example, when the first state (or the second state) is changed to the second state (or the first state) in the portrait mode, the electronic device 100 in which as a height of the display area is maintained and a width of the display area is changed may be implemented.

The electronic device 100 of FIGS. 1A to 3B may be referred to as a slidable electronic device, in terms of the second housing 220 (or the first housing 210) sliding with respect to the first housing 210 (or the second housing 220). The electronic device 100 may be referred to as a rollable electronic device, in terms of the display 140 being rolled into the first housing 210.

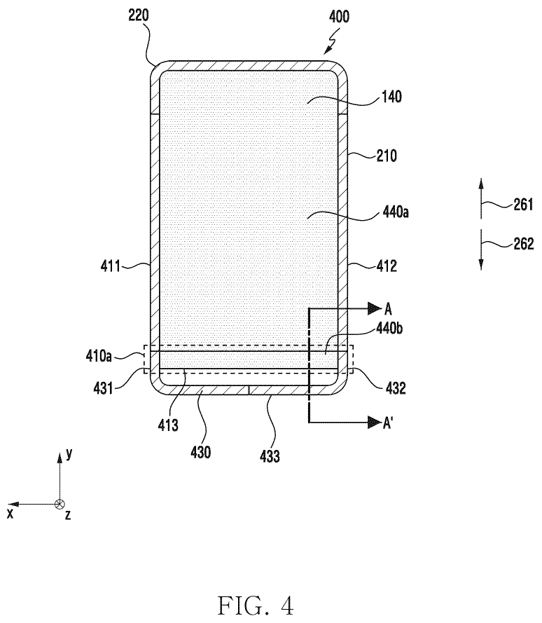

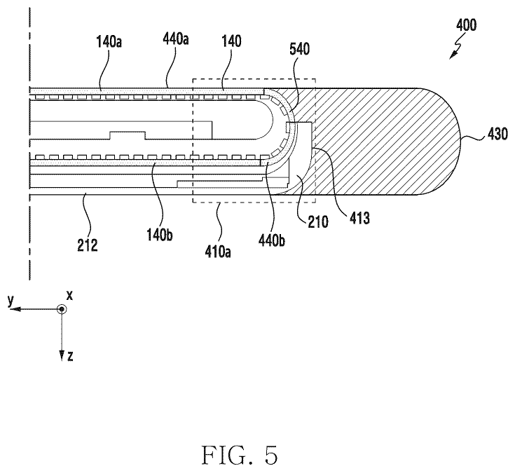

FIG. 4 is a diagram illustrating a top plan view of an example electronic device including an external frame according to various embodiments. FIG. 5 is a partial cross-sectional view of an example electronic device including an external frame according to various embodiments. FIG. 5 is a cross-sectional view of the electronic device 100 taken along A-A′ of FIG. 4.

Referring to FIGS. 4 and 5, an electronic device 400 (e.g., the electronic device 100 of FIGS. 1A to 3B) may include a first housing 210, a second housing 220 configured to be movably coupled to the first housing 210, and a display 140 configured to be partially rolled into the first housing 210 according to a movement of the second housing 220. A visible area of the display 140 may be varied according to the movement of the second housing 220. As the second housing 220 moves in a first direction 261, a second area 140b of the display 140 may be slid-out from the inside of the first housing 210, and as the second housing 220 moves in a second direction 262, the second area 140b may be slid-in to the inside of the first housing 210. The display 140 may be referred to as a flexible display, a rollable display, or a stretchable display, in terms of capable of deformation rolled partially into the first housing 210 and slid-in or slid-out according to the movement of the second housing 220.

The display 140 may include a planar portion 440a and a curved portion 440b. In the first state, the first area 140a may include the planar portion 440a. In the first state, a portion of the second area 140b may include the curved portion 440b. A position of the curved portion 440b in the second area 140b may be changed. The curved portion 440b may be moved according to a change in a state of the electronic device 400. For example, in the first state, the curved portion 440b may be a portion of the second area 140b in contact with the first area 140a. In the second state, the curved portion 440b may be another portion of the second area 140b spaced apart from a boundary of the first area 140a. The other portion of the second area 140b may include a periphery of the display 140. The other portion of the second area 140b may be a periphery spaced far away apart from a boundary between the first area 140a and the second area 140b among the edge of the second area 140b. In a state between the first state and the second state, the curved portion 440b may be a portion of a remaining area except for the portion of the second area 140b and the other portion of the second area 140b.

A first cover (e.g., the first cover 311 of FIG. 2A) of the first housing 210 may form a portion of an exterior of the electronic device 400. The first cover 311 may provide a portion of a side surface of the electronic device 400 visually exposed to the outside. The first housing 210 may provide a first side surface 411, a second side surface 412, and a third side surface 413 through the first cover 311. The first side surface 411 and the second side surface 412 may extend in a direction parallel to a first direction 261 or a second direction 262, which is a moving direction of the second housing 220. The third side surface 413 may be disposed between the first side surface 411 and the second side surface 412. The third side surface 413 may extend in a direction perpendicular to the first direction 261 and the second direction 262. For example, the third side surface 413 may be perpendicular to the first side surface 411 and the second side surface 412. The third side surface 413 may be a side surface spaced far away from the second housing 220 among the side surfaces 411, 412, and 413 of the first housing 210.

The second area 140b of the display 140 may be slid-in to the inside of the first housing 210 or slid-out to the outside of the first housing 210 along the third side surface 413. The curved portion 440b of the display 140 may be a portion in which a surface of the display 140 is temporarily changed by the display 140 being slid-out from the first housing 210 or slid-in to the first housing 210. The curved portion 440b, which is a portion that repeats bending and unfolding according to a change in a state of the electronic device 400, may be vulnerable to external impact. While the curved portion 440b is bent, an outer surface (e.g., a surface having a small curvature) of the curved portion 440b may be elongated, and an inner surface (e.g., a surface having a large curvature) of the curved portion 440b may be compressed. While the curved portion 440b is in a deformed state from its original shape, stress may be accumulated. The curved portion 440b may be disposed in a portion 410a of the first housing 210 on which the third side surface 413 of the electronic device 400 is disposed. The display 140 may be rolled in the portion 410a of the first housing 210. The curved portion 440b rolled along the third side surface 413 may be disposed on the portion 410a of the first housing 210. The portion 410a of the first housing 210 may have a round shape corresponding to a shape in which the display 140 is to be rolled, in order to store the bent display 140. The portion 410a of the first housing 210 may be a portion located near a bending portion into which the display 140 is rolled. The periphery of the bending portion may be a portion of the side surfaces 411 and 412 of the first housing 210 surrounding a side of the bending portion in which the display 140 is rolled, or when the first side surface 411 or the second side surface 412 of the first housing 210 is viewed vertically, a portion right next to the bending portion in which the display 140 is rolled or a side surface of the first housing 210 overlapping to the bending portion.

The electronic device 400 may further include an external frame 430 to protect the curved portion 440b that is a weak portion of the display 140. The external frame 430 may be connected to the portion 410a of the first housing 210 in which the display 140 is rolled. The external frame 430 may protect the curved portion 440 or the portion 410a from an external impact transmitted to the curved portion 440 or the portion 410a.

The external frame 430 may reduce an impact applied from an external structure to an electronic device 100 when the electronic device 100 falls. For example, the external frame 430 may reduce an impact transmitted to the electronic device 100 by absorbing the impact occurring when the external structure of the electronic device 100 collides with the electronic device 100.

The external frame 430 may include a portion spaced apart from a housing 210 and 220, thereby reducing an impact directly transmitted to the first housing 210. The external frame 430 may reduce a direct contact of the curved portion 440b with the external structure. The external frame 430 may be arranged to partially surround the curved portion 440b and the portion 410a of the first housing 210, thereby reducing the transmission of impact to the curved portion 440b, which is a vulnerable portion of the display 140.

The external frame 430 may be referred to as a protective member in terms of protecting a portion of the electronic device 100 or a portion of the display 140.

The external frame 430 may include connection parts 431 and 432 and a frame part 433. The external frame 430 may be connected to the first side surface 411 and the second side surface 412. The connection parts 431 and 432 may be fastened to a portion of the first housing 210. The first connection part 431 may be fastened to the first side surface 411 extended parallel to a first direction 261 or a second direction 262. The first connection part 431 may be extended along the second direction 261. The second connection part 432 may be fastened to the second side surface 412 extended parallel to the first direction 261 or the second direction 262. The second connection part 432 may be extended along the second direction 262.

The first connection part 431 and the second connection part 432 may be attached and fasten to the first side surface 411 and the second side surface 412 of the first housing 210. The first connection part 431 and the second connection part 432 may be rotatably coupled with respect to the first housing 210 within a specified angle range.

The frame part 433 may be disposed between the first connection part 431 and the second connection part 432. The frame part 433 may be formed in various shapes. The frame part 433 may be formed in a shape corresponding to a shape of the third side surface 413. The frame part 433 may have a shape of a bar, a rack, a plate, and a beam connecting the first connection part 431 and the second connection part 432.

The frame part 433 may be extended in a direction parallel to the first direction 261 and the second direction 262. For example, the frame part 433 may be parallel to the third side surface 413 of the first housing 210. The frame part 433 may be spaced apart from the portion 410a of the first housing 210. The frame part 433 may be spaced apart from the third side surface 413 facing the frame part 433. The frame part 433 may surround the third side surface 413 or the portion 410a of the first housing 210. For example, when the frame part 433 is viewed in the first direction 261, the frame part 433 may be overlapped with the third side surface 413 or the portion 410a of the first housing 210.

The frame part 433 may protect the curved portion 440 or the portion 410a from an external impact transmitted to the curved portion 440 or the portion 410a. For example, when the electronic device 400 falls and collides with an external structure (e.g., the ground or a desk), the frame part 433 surrounding the third side 413 or the portion 410a of the first housing 210 may reduce the transmission of impact to the portion 410a of the first housing 210 or the curved portion 440b of the display 140. The external frame 430 may include the frame part 433 spaced apart from the first housing 210, thereby reducing the amount of impact transmitted from the frame part 433 to the portion 410a of the first housing 210.

A display area of the display 140 may include a planar portion 440a of the display 140 and a portion 540 of a curved portion 440b of the display 140 visible from the portion 410a of the first housing 210. The portion 410a of the first housing 210 may be partially opened in a direction (e.g., −z axis direction) in which the first area 140a faces so that the portion 540 of the curved portion 440b of the display 140 is used as the display area of the display 140. For example, in the portion 410a of the first housing 210, a height of the third side surface 413, among the first side surface 411, the second side surface 412, and the third side surface 413, may be lower than a height of the first side surface 411 and the second side surface 412. For example, the first side surface 411 and the second side surface 412 may be formed by a first height from a first plate 212. The third side surface 413 may be formed by a second height lower than the first height from the first plate 212. As an edge portion (e.g., decoration or trim) of the first housing 210 covering the curved portion 140b of the display 140 is removed at the portion 410a of the first housing 210, the portion 540 of the curved portion 140b adjacent to the planar portion 440a from among the curved portion 140b may be exposed to the outside. The portion 540 of the curved portion 140b may be continuous from a periphery of the planar portion 440a. As the portion 540 of the curved portion 140b is visible, the display area of the display 140 may be extended to the portion 540 of the curved portion 140b.

According to the above-described embodiment, the electronic device 400 including the external frame 430 may protect the curved portion 140b of the display 140 from an external structure. The first housing 210 may be configured to open the portion 540 of the curved portion 140b, thereby expanding the display area of the display 140. For example, the planar portion 140a and the portion 540 of the curved portion 140b visible to the outside of the housing may be used as a display area of the display 140.

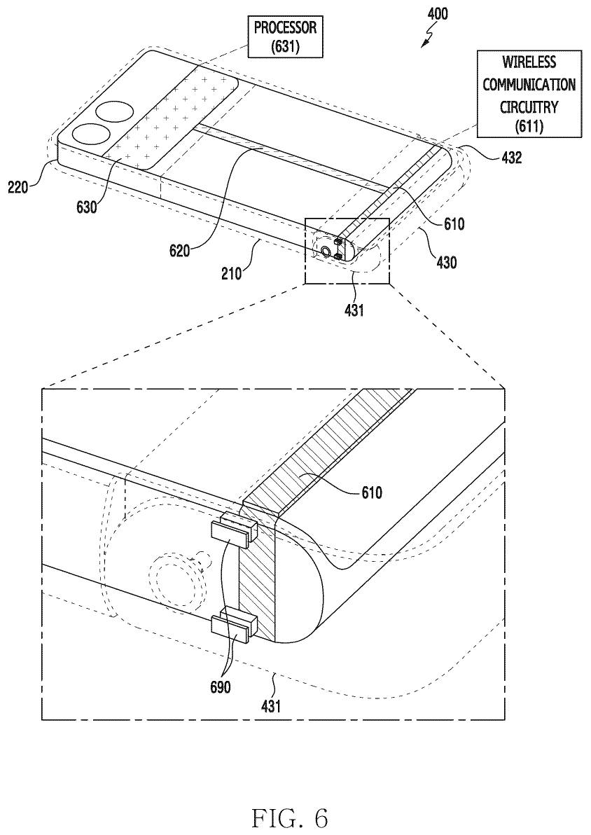

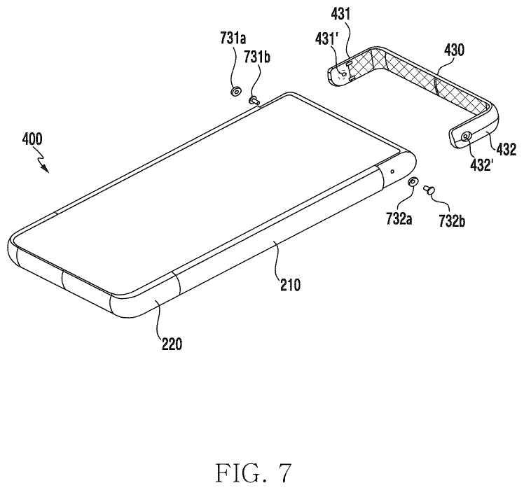

FIG. 6 is a perspective view illustrating an example electronic device including an external frame acting as an antenna radiator according to various embodiments. FIG. 7 is an exploded perspective view of an example electronic device including an external frame acting as an antenna radiator according to various embodiments.

Referring to FIG. 6, an electronic device 400 may use an external frame 430 as an antenna radiator. For example, the external frame 430 may include a conductive portion acting as an antenna radiator. At least a portion of the external frame 430 may be formed of a conductive portion. The conductive portion may include a plurality of conductive portions. The conductive portion may be disposed within the external frame 430 and on a surface of the external frame 430. The conductive portion may be spaced apart by a non-conductive portion. For example, the non-conductive portion may be disposed between a plurality of conductive portions. For another example, the conductive portion may be formed with a conductive pattern. The conductive pattern may be a pattern extended along a surface of the external frame. There may be a plurality of conductive patterns, and each conductive pattern may be spaced apart. One of the conductive patterns may be formed in parallel to another conductive pattern.

The electronic device 400 may include a first PCB 610, a second PCB 630 (e.g., the PCB 324 of FIG. 2A), and a FPCB 620 (e.g., the FPCB 325 of FIG. 2A). The first PCB 610 may be disposed in a first housing 210. The first PCB 610 may be disposed at a lower end of the first housing 210 (e.g., the portion 410a of the first housing 210 of FIG. 4). The first PCB 610 may be electrically connected to wireless communication circuitry 611 disposed adjacent to an antenna module or an antenna radiator. The first PCB 610 may be connected to a terminal 690 exposed to the outside of the first housing 210. The electronic device 400 may include a plurality of terminals in contact with the first PCB 610. For example, the terminal 690 may be contacted to a first connection part 431 and a second connection part 432 of the external frame 430. The terminal 690 may be exposed from the side surface (e.g., a first side surface 411) of the first housing 210 toward the first connection part 431, and another terminal different from the terminal 690 may be exposed from another side surface (e.g., the second side surface 412) of the first housing 210 toward a second connection part 432. The terminal 690 may be in contact with a conductive portion (e.g., a pad or an exposed conductive portion) of the first PCB 610 in the first housing 210, and the first connection part 431 facing the first side surface 411 of the first housing 210. Another terminal may be in contact with another conductive portion of the first PCB 610 in the first housing 210, and the second connection part 432 facing the second side surface 412 of the first housing 210. The terminal 690 may include a conductive pad, a conductive C-clip, a conductive contact, or a conductive pogo pin exposed to a side surface of the first housing 210.

The electronic device 400 may include wireless communication circuitry 611 and/or a processor 631. The wireless communication circuitry 611 and the processor 631 may be electrically and/or operably connected with each other by an electronic component such as a communication bus. The type and/or number of hardware components included in the electronic device 400 are not limited to those illustrated in FIG. 6.

The wireless communication circuitry 611 of the electronic device 400 may wirelessly communicate with an external electronic device through the external frame 430 acting as an antenna radiator. The wireless communication circuitry 611 of the electronic device 400 may include a hardware component for supporting transmission and/or reception of an electrical signal between the electronic device 400 and the external electronic device. For example, the wireless communication circuitry 611 may include at least one of a MODEM, an antenna, and an Optic/Electronic (O/E) converter. The communication circuitry 611 may support transmission and/or reception of an electrical signal, based on various type of protocols such as ethernet, Local Area Network (LAN), Wide Area Network (WAN), Wireless Fidelity (WiFi), Bluetooth, Bluetooth Low Energy (BLE), ZigBee, Long Term Evolution (LTE), and 5G New Radio (NR).

The first PCB 610 may be electrically connected to the second PCB 630 through the FPCB 620. Although the present drawing illustrates that the first PCB 610 and the second PCB 630 are connected through the FPCB 620, the disclosure is not limited thereto. The electronic device 400 may include at least one of a plurality of FPCBs and PCB to connect the first PCB 610 and the second PCB 630.

Another PCB may be disposed between the first PCB 610 and the second PCB 630. For example, the other PCB may be disposed on an upper end of the first housing 210, and the other PCB and the first PCB 610 may be connected to an FPCB. The other PCB may be connected to another FPCB and the second PCB 630.

The second PCB 630 may be disposed in the second housing 220. The second PCB 630 may be electrically connected to the processor 631. The processor 631 of the electronic device 400 may include a hardware component for processing data based on one or more instructions.

For example, the hardware component for processing data may include an Arithmetic and Logic Unit (ALU), a Field Programmable Gate Array (FPGA), and/or a Central Processing Unit (CPU). The number of the processor 631 may be one or more. For example, the processor 631 may have a structure of a multi-core processor such as a dual core, a quad core, or a hexa core. The processor 631 may be configured to wirelessly communicate with an external electronic device through the wireless communication circuitry 611 and the external frame 430. The processor 631 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

Referring to FIG. 7, an external frame 430 may be fastened to a first housing 210. The external frame 430 may be fastened to a side surface of a portion (e.g., the portion 410a of FIG. 4) of the first housing 210 through fastening members 731a, 731b, 732a, and 732b. Connection parts 431 and 432 of the external frame 430 may include the fastening members 731a, 731b, 732a, and 732b and structures 431′ and 432′ for fastening. For example, the first connection part 431 may be fastened through a first pin 731b and a washer 731a. The first pin 731b may be fastened to the first housing 210, by passing through the washer 731a and a structure 431′ (e.g., an opening) of the first connection portion 431. The second pin 732b may be fastened to the first housing 210, by passing through the washer 732a and the structure 432′ of the second connection portion 432. The washer 731a or 732a may be an o-ring. The washer 731a or 732a may be omitted. The external frame 430 may be fastened to the first housing 210 by the fastening members 731a, 731b, 732a, and 732b, or rotatably coupled to the first housing 210 by the first pin 731b and the second pin 732b. Among the fastening members, the first pin 731b and the second pin 732b may be bolts with spirals, and the washers 731a and 732a may be nuts with spirals corresponding to the spirals of the first pin 731b and the second pin 732b. The first housing 210 may include a structure for coupling of the external frame 430. For example, the first housing 210 may include a structure for coupling formed in a portion (e.g., the portion 410a of FIG. 4) of the first housing 210. For example, the structure may correspond to a shape of a portion of the external frame 430. The structure may be a groove formed to correspond to shapes of the connection portions 431 and 432 of the external frame 430. As the first housing 210 has a step in the portion 410a, a continuous surface is provided even though the external frame 430 is coupled to the first housing 210.

The external frame 430 may include a conductive portion. For example, the external frame 430 may include a conductive portion. The conductive portion of the external frame 430 may be in contact with a terminal 690 or may be electrically connected to the terminal 690. The conductive portion of the external frame 430 may be fed through the terminal 690. The external frame 430 may be configured to, through a designated frequency band, transmit a signal transmitted from a processor 631 or a wireless communication circuitry 611 to an external electronic device, or receive a signal to be transmitted to the processor 631 or the wireless communication circuitry 611 from an external electronic device.

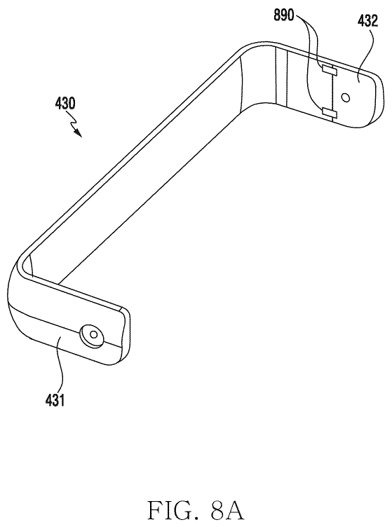

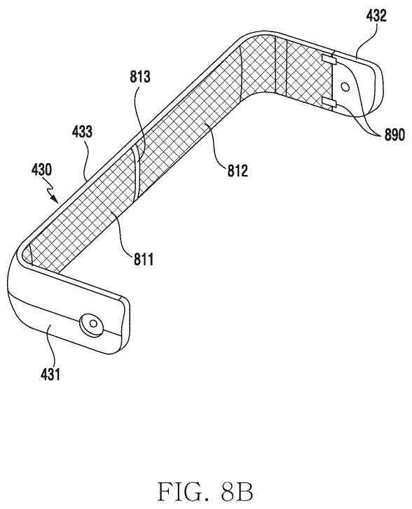

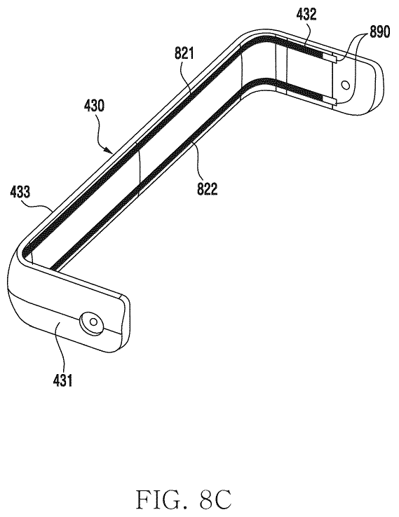

The conductive portion of the external frame 430 may be disposed in various forms. An arrangement of the conductive portion will be described in greater detail below with reference to FIGS. 8A, 8B, and 8C.

FIG. 8A is a perspective view illustrating an external frame acting as an antenna radiator according to various embodiments. FIG. 8B is a perspective view illustrating an external frame including a conductive portion acting as a segmented antenna radiator according to various embodiments. FIG. 8C is a perspective view illustrating an external frame including a conductive portion acting as an antenna radiator providing multiple bands according to various embodiments.

Referring to FIG. 8A, at least a portion of an external frame 430 may be formed of a conductive portion. The external frame 430 may be formed of an integrally formed conductive portion, but may also include partially a non-conductive portion according to characteristics of an antenna radiator configured to communicate in a designated frequency band.

The external frame 430 may further include connection members 890 for contact with a terminal (e.g., the terminal 690 of FIG. 6). The connection members 890 may be a conductive contact or a conductive pad for electrical connection with a terminal 690. Each of the connection members 890 may have a configuration for maintaining the contact with the terminal 690. The connection members 890 may be referred to as a pad, a contact portion, or a contact, in terms of being contacted and electrically connected to the terminal 690.

In a case that the external frame 430 is formed of only a conductive portion such as metal, the connection members 890 may be omitted. In a case that the external frame 430 forms a conductive portion inside and surrounds the conductive portion by a non-conductive portion, the conductive portion and the connection members 890 may be configured to be connected with each other.

Referring to FIG. 8B, an external frame 430 may include a first conductive portion 811 and a second conductive portion 812. The first conductive portion 811 may be spaced apart from the second conductive portion 812. The first conductive portion 811 and the second conductive portion 812 acting as antenna radiators may act as segmented antennas. The external frame 430 may include a non-conductive portion 813 in a segment portion. The first conductive portion 811 may be extended from a first connection part 431 to the non-conductive portion 813 in a frame part 433. The second conductive portion 812 may be extended from a second connection part 432 to the non-conductive portion 813 in the frame part 433. The first conductive portion 811 may be connected to a terminal 690 through connection members (not shown) connected to the first conductive portion 811, and the second conductive portion 812 may be connected to another terminal through connection members 890 connected to the second conductive portion 812. In a case that the first conductive portion 811 and the second conductive portion 812 are exposed to a side surface of the first housing 210, the connection members 890 may be omitted. The first conductive portion 811 and the second conductive portion 812 may be covered by a non-conductive portion extended from the non-conductive portion 813. Lengths of the first conductive portion 811 and the second conductive portion 812 may be determined according to a frequency band used. For example, Lengths of the first conductive portion 811 and the second conductive portion 812 may be the same. However, those are not limited thereto, and the first conductive portion 811 and the second conductive portion 812 may be different. Although it is described that the conductive parts 811 and 812 disposed on the external frame 430 act as segmented antennas, the disclosure is not limited thereto. For example, the conductive portions 811 and 812 disposed on the external frame 430 may act as slit antenna, and support multiple bands.

Referring to FIG. 8C, an external frame 430 may include a first conductive pattern 821 and a second conductive pattern 822. The first conductive pattern 821 may be extended from the first connection part 431 of the external frame 430 to the second connection part 432. The second conductive pattern 822 may be extended parallel to the first conductive pattern 821. The second conductive pattern 822 may be spaced apart in a direction perpendicular to an extended direction of the first conductive pattern 821. Each of the first conductive pattern 821 and the second conductive pattern 822 may act as an antenna radiator. The first conductive pattern 821 and the second conductive pattern 822, which act as antenna radiators respectively, may be configured to communicate with an external electronic device in different frequency bands. For example, wireless communication circuitry (e.g., wireless communication circuitry 611 of FIG. 6) (or a processor (e.g., the processor 631 of FIG. 6)) may be configured to communicate with an external electronic device using a first frequency band through the first conductive pattern 821, and an external electronic device using a second frequency band different from the first frequency band through the second conductive pattern 822.

A plurality of connection members may be located in each of the first connection part 431 and the second connection part 432. The first conductive pattern 821 may be in contact with one of connection members (not shown) located in the first connection part 431 and one of connection members 890 located in the second connection part 432. The first conductive pattern 821 may be extended from one of the connection members 890 of the first connection part 431 to one of the connection members 890 of the second connection part 432. The second conductive pattern 822 may be in contact with another one of connection members (not shown) located in the first connection part 431 and another one of the connection members 890 located in the second connection part 432. The second conductive pattern 822 may be extended from another one of the connection members of the first connection part 431 to another one of the connection members 890 of the second connection part 432. In a case that the first conductive pattern 821 and the second conductive pattern 822 are exposed to the side surface of the first housing 210, the connection members 890 may be omitted. The first conductive pattern 821 and the second conductive pattern 822 may be covered by a non-conductive portion.

The non-conductive portion described through FIGS. 8A, 8B and 8C may be a polymer material (e.g., acrylonitrile butadiene styrene copolymer (ABS), polypropylene (PP), polyethylene (PE), polymethly methacrylate acrylic (PMMA), or polycarbonate (PC)). The external frame 430 including a conductive portion (e.g., the conductive portions 811 and 812 or the conductive patterns 821 and 822) and a non-conductive portion (e.g., the non-conductive portion 813) may be manufactured by a double injection molding process. For another example, the conductive patterns 821 and 822 may be patterned on a body of the external frame 430 formed of a polymer, or pre-formed conductive patterns 821 and 822 may be attached.

The electronic device according to the above-described embodiment may include an external frame 430 acting as an antenna. In a case that an antenna is disposed in the portion 410a of the first housing 210, distortion of a signal may occur due to a conductive material disposed on the curved portion 440b of the display 140. As the external frame 430 is spaced apart from the curved portion 440b of the display 140, performance of the antenna using the external frame 430 including a conductive member may be improved.

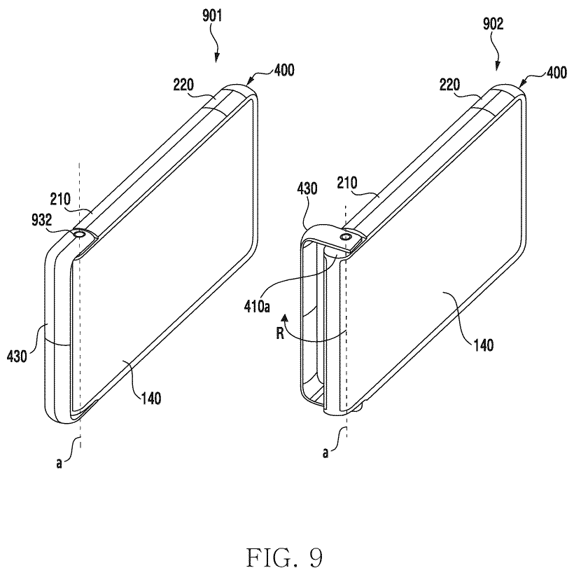

FIG. 9 is a perspective view illustrating an example electronic device including a rotatable external frame according to various embodiments.

Referring to FIG. 9, an external frame 430 of an electronic device 400 may rotate with respect to a first housing 210. The external frame 430 may be parallel to the first housing 210 and a second housing 220 in a first state 901. For example, in the first state 901, an angle between the external frame 430 and the first housing 210 may be about 180 degrees.

The external frame 430 may be coupled to the first housing 210 by a fastening member (e.g., fastener) 932. The fastening member 932 may include a pin (e.g., the first pin 731b and the second pin 732b of FIG. 7). The pin-shaped fastening member 932 may rotatably couple the external frame 430 with respect to the first housing 210. The fastening member 932 may be referred to as a pin, in terms of having a thin rod shape, and fastening or connecting the external frame 430 and the first housing 210.

The external frame 430 may rotate in a rotation direction R with respect to the first housing 210 or the second housing 220 based on an axis a. By the external frame 430 rotated with respect to the first housing 210 or the second housing 220, the electronic device 400 may stand from a bottom contacted with a side surface (e.g., the first side surface 411 or the second side surface 412 of FIG. 4).

In a second state 902, the external frame 430 of the electronic device 400 may have a slope with respect to the first housing 210 or the second housing 220. The second state 902 may be a state rotated at a predetermined angle from the first state 901 in the rotation direction R. The predetermined angle may be determined from a shape of the external frame 430 and a portion 410a of the first housing 210. The predetermined angle may be about 90 degrees in the rotation direction R. An angle between the external frame 430 of the electronic device 400 and the first housing 210 may vary between about 90 degrees and 180 degrees. For example, the external frame 430 may rotate at an angle between about 0 degrees and 90 degrees with respect to the first housing 210.

For a rotation of the external frame 430, the first housing 210 may include a structure (e.g., a groove or a step) for the external frame 430 in a portion (e.g., the portion 410a of FIG. 4) of the first housing 210. A shape of an area of the first housing 210 may be determined to reduce interference between connection portions 431 and 432 of the external frame 430, which is disposed in an area of a dented first housing 210, and another area of the first housing 210. When the external frame 430 rotates, an area of the dented first housing 210 may be formed so that an area through which the external frame 430 passes does not overlap with the first housing 210. A shape of the area may allow the external frame 430 rotating in the rotation direction R but limit the external frame 430 rotating in a direction opposite to the rotation direction R. For example, the external frame 430 may serve as a stopper for limiting the movement in a direction opposite to the rotation direction R.

In the electronic device 400 according to the above-described embodiment, it is described that the external frame 430 rotates with respect to the first housing 210 or the second housing 220 in a rotation direction R, but the external frame 430 may also rotate with respect to the first housing 210 or the second housing 220 in a direction opposite to the rotation direction R. For another example, the shape of the area may be configured to cause the external frame 430 to rotate with respect to the first housing 210 or the second housing 220 in the rotation direction R or the direction opposite to the rotation direction R.

In the first state 901, the external frame 430 may surround a portion 410a of the housing 210 in which a curved portion of the display 140 is disposed and a curved portion of the display 140 visible through an open portion of the portion 410a. In the first state 901, when looking at a side surface of the first housing 210 in which the curved portion of the display 140 is disposed, the curved portion of the display 140 may be overlapped with the external frame 430. While changing from the first state 901 to the second state 902, the external frame 430 may be rotated to open the curved portion of the display 140. In the second state 902, when looking at the side surface of the first housing 210 in which the curved portion of the display 140 is disposed, a portion of the curved portion of the display 140 may be exposed to the outside.

According to the above-described embodiment, while a user is gripping the electronic

device 400 or using it in hand, even when the electronic device 400 maintained in the first state is separated from the user and falls away, the external frame 430 may prevent and/or block the curved portion of the display 140 from being directly impacted by the external structure. While using the electronic device 400 by placing it on the floor or standing it on a table, the electronic device 400 in the second state may be stood by the side surfaces of the first housing 210 and the second housing 220 and the external frame 430.

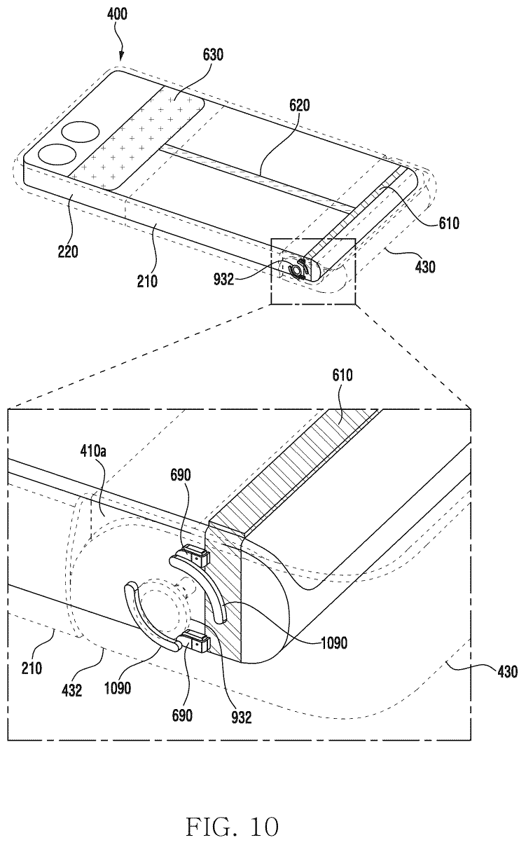

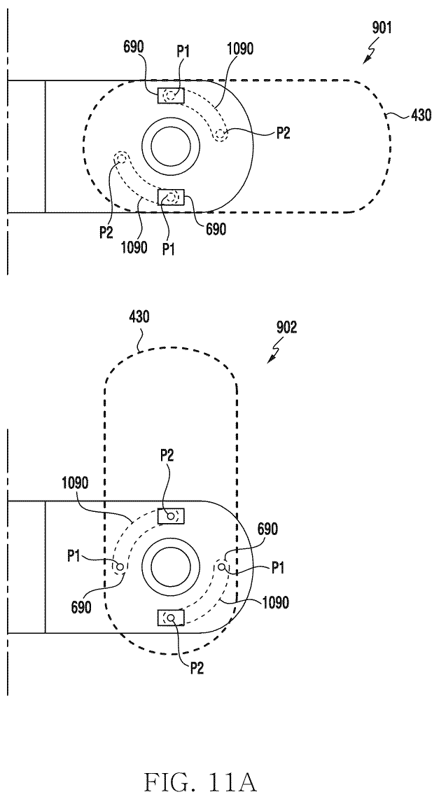

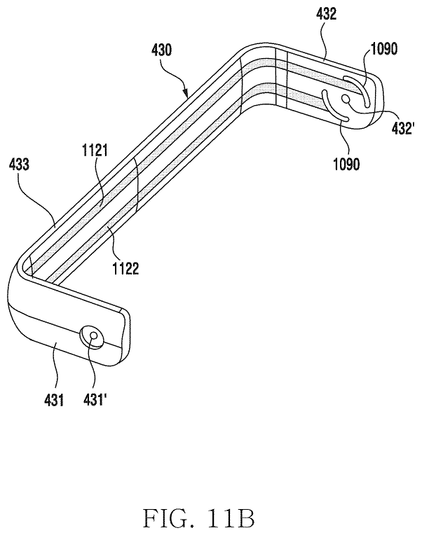

FIG. 10 is a perspective view illustrating an interior of an example electronic device including a rotatable external frame according to various embodiments. FIG. 11A is a diagram illustrating a connection relationship between a terminal and a conductive portion according to a rotation of an external frame according to various embodiments. FIG. 11B is a perspective view illustrating an external frame including a contact for maintaining contact with a terminal while rotating according to various embodiments.

Referring to FIGS. 10, 11A, and 11B, an electronic device 400 may include a structure for electrically connecting an external frame 430 acting as an antenna and a first PCB 610, while being changed from a first state (e.g., the first state 901 of FIG. 9) (or a second state) to the second state (e.g., the second state 902 of FIG. 9) (or the first state).

An external frame 430 may include a connection member 1090 extending in an arc shape. The connection member 1090 may be disposed on a surface of connection parts 431 and 432 of the external frame. The surface of the connection parts 431 and 432 may be a surface facing a portion 410a of a first housing 210. The connection member 1090 may extend, on the surface of the connection parts 431 and 432, along a periphery of a pin-shaped fastening member 932. The arc of the connection member 1090 may be a portion of a circle formed around a center of the pin-shaped fastening member 932. For example, the connection member 1090 may be spaced apart from the fastening member 932 and extended along a portion of an outer circumference of the fastening member 932.

In a first state 901, the connection member 1090 may be contacted with a terminal 690 at a first position P1. Since the connection member 1090 also rotates according to a rotation of an external frame 430, in a second state 902, the connection member 1090 may be contacted a terminal 690 at a second position P2. While being changed from the first state 901 to the second state 902, the terminal 690 may be contacted with the connection member 1090 between the first position PI and the second position P2 of the connection member 1090. The external frame 430 including the arc-shaped connection member 1090 may maintain electrical connection with a first PCB 610 while being changed from the first state 901 to the second state 902, through the connection member 1090 and the terminal 690. The first PCB 610 may be connected to a second PCB 630 on which a processor is mounted through a FPCB 620. The processor mounted on the second PCB 630 may be configured to wirelessly communicate with an external electronic device through conductive patterns 1121 and 1122 of the external frame 430. The external frame 430 may be formed of a conductive material, instead of the conductive patterns 1121 and 1122, as illustrated in FIG. 8A, or conductive portions 811 and 812 segmented each other may be used as an antenna radiator, as illustrated in FIG. 8B. The connection member 1090 may be disposed at both ends of the conductive patterns 1121 and 1122.

According to the above-described embodiment, the electronic device 400 may stably maintain a communication channel with an external electronic device by maintaining contact with the conductive pattern (or a conductive portion, a conductive material) of the external frame 430 through the arc-shaped connection member 1090, even when the external frame 430 rotates and changes a state, or while changing the state.

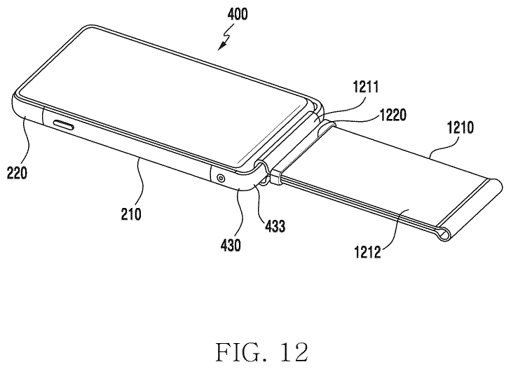

FIG. 12 is a perspective view illustrating an example electronic device including an external frame in which an accessory may be fastened according to various embodiments.

Referring to FIG. 12, an electronic device 400 may include a first housing 210, a second housing 220 movably (or slidably) coupled to the first housing 210, and an external frame 430 connected to the first housing 210 and providing a space through a portion spaced apart from the first housing 210.

Both ends (e.g., the connection parts 431 and 432 of FIG. 4) of the external frame 430 may be connected to the first housing 210. The external frame 430 may include a frame part 433 disposed between both ends and spaced apart from the first housing 210. The frame part 433 may provide a space capable of being fastened with an accessory 1210 by being spaced apart from the first housing 210. For example, when the accessory 1210 is a band or strap, a portion 1211 of the accessory 1210 may surround at least a portion of the frame part 433. The accessory 1210 may be coupled to the external frame 430 by surrounding at least a portion of the frame part 433. The accessory 1210 may further include a fixing member (e.g., fastener) 1220 to firmly maintain a fastening between the accessory 1210 and the external frame 430. The fixing member 1220 may be coupled to the accessory 1210 such that the external frame 430 and the portion 1211 of the accessory 1210 are in closely contact with each other. The fixing member 1220 may have a ring or band shape. However, the disclosure is not limited thereto, and the fixing member 1220 may have a clip or fitting structure fitted into a band or strap. Another portion 1212 of the accessory 1210 may be worn on a part (wrist or arm) of a user's body, or fastened to another external object (e.g., a bag ring or a bicycle cradle).

According to the above-described embodiment, an electronic device 400 may fasten various accessories to the external frame 430, thereby improving user convenience.

An electronic device may include a deformable flexible display. The flexible display may be configured to be deformable and may be vulnerable to external impact. A slidable electronic device may require a method for mitigating an impact.

The technical problems addressed in this disclosure are not limited to those described above, and other technical problems not mentioned herein will be clearly understood by those having ordinary knowledge in the art to which the present disclosure belongs, from the following description.

According to an example embodiment, an electronic device (e.g., the electronic device 100 of FIG. 1A, the electronic device 400 of FIG. 4) may include: a first housing (e.g., the first housing 210 of FIG. 1A) and a second housing (e.g., the second housing 220 of FIG. 1A). The second housing may be configured to be movably coupled with respect to the first housing. The electronic device may further include a flexible display (e.g., the display 140 of FIG. 1A). The flexible display may be configured to move to change a visible area according to a movement of the second housing. The electronic device may further include an external frame (e.g., the external frame 430 of FIG. 4). The external frame may be connected to a portion of the first housing. The external frame may be configured to protect a bending portion of the flexible display from external impact.

According to an example embodiment, the portion of the first housing may be a portion of the first housing positioned next to the bending portion.

According to an example embodiment, the electronic device may include the frame part spaced apart from a portion of the first housing and configured to reduce damage of the flexible display by external impact. It is possible to increase the durability of the electronic device by reducing a direct impact on the first housing surrounding the curved portion of the flexible display 140 that is a vulnerable portion of the electronic device.

According to an example embodiment, the external frame may include a frame part spaced apart from the first housing, thereby reducing the amount of impact transmitted from the frame part to the portion of the first housing. The portion may surround the bending portion of the flexible display.

According to an example embodiment, the external frame may include a conductive portion (e.g., the first conductive portion 811, the second conductive portion 812 of FIG. 8B, the first conductive pattern 821, the second conductive pattern 822, or the first conductive pattern 1121 or the second conductive pattern 1122 of FIG. 11B).

The external frame may act as an antenna radiator by including a conductive portion. The external frame may be disposed outside the first housing to separate a physical distance between the antenna radiator and the display. Distortion of a signal transmitted and received through an antenna radiator separated from the display may be reduced.

According to an example embodiment, electronic device may further include wireless communication circuitry (e.g., wireless communication circuitry 611 of FIG. 6). Wireless communication circuitry may be configured to wirelessly communicate with the external electronic device through the conductive portions. The electronic devices may further include a FPCB (e.g., the FPCB 620 of FIG. 6). The FPCB may be electrically connected to wireless communication circuitry 11 and the conductive portions.

According to an example embodiment, a printed circuit board in which the wireless communication circuit is disposed in the first housing in which the antenna radiator is located through the FPCB and a printed circuit board in which a processor is disposed in the second housing may be electrically connected.

According to an example embodiment, a first housing may further include a terminal (e.g., the terminal 690 of FIG. 6). The conductive portions may be electrically connected to a terminal disposed on the portion the first housing.

According to an example embodiment, the terminal may be connected to the printed circuit board inside the first housing, exposed to the outside, and coupled with the conductive portion of the external frame, so that the external frame may act as an antenna radiator.

According to an example embodiment, the terminal may include a movable terminal including a C-clip or pogo pins.

According to an example embodiment, based on the external frame being physically coupled to the first housing through a movable terminal exposed to the outside, a bonding force between the terminal and the conductive portion may be maintained. As a movable terminal exposed to the first housing, the terminal and the conductive portion may be electrically connected after the external frame is assembled despite the tolerance of the external frame or the first housing 210 assembly and manufacturing.

According to an example embodiment, the external frame may include a first conductive pattern (e.g., the first conductive pattern 821 of FIG. 8C or the first conductive pattern 1121 of FIG. 11B). The first conductive pattern may extend from one end to another end of the external frame. The external frame may further include a second conductive pattern (e.g., the second conductive pattern 822 of FIG. 8C or the second conductive pattern 1122 of FIG. 11B). The second conductive pattern may be spaced apart from the first conductive pattern, and parallel to the first conductive pattern. Each of the first conductive pattern and the second conductive pattern may be configured to act as an antenna radiator.

According to an example embodiment, the external frame may wirelessly communicate with an external electronic device through the conductive patterns patterned on the external frame. Each of the conductive patterns may act as an antenna radiator. Each antenna radiator may support a different frequency band.

The electronic device may further include at least one of wireless communication circuitry (e.g., the wireless communication circuitry 611 of FIG. 6). The wireless communication circuitry may communicate with an external electronic device using a first frequency band through the first conductive pattern. The wireless communication circuitry may be configured to communicate with an external electronic device using a second frequency band through the second conductive pattern.

According to an example embodiment, the electronic device may support a plurality of frequency bands through a plurality of conductive patterns.

According to an example embodiment, an external frame may include a non-conductive portion and conductive portions. The non-conductive portion may form an outer surface of the external frame. The conductive portions may be spaced apart from each other. The conductive portions may be configured to act as an antenna radiator.

According to an example embodiment, the conductive portions disposed on the external frame may act as slit antennas or segmented antennas, and support multiple bands.

According to an example embodiment, the external frame may further include a connection portion (e.g., connection portions 431 and 432 of FIG. 4). The connection portions may be rotatably connected to a portion of the first housing.

According to an example embodiment, an angle between the external frame and the first housing may vary between 90 degrees and 180 degrees.

According to the above-described embodiment, the rotatably connected external frame may stably stand the electronic devices on the floor or table through the rotation of the external frame.

According to an example embodiment, the external frame may include a contact portion (e.g., the connection member 890 of FIGS. 8A to 8C or the connection member 1090 of FIG. 10). The contact portion may be connected to a conductive portion of the external frame and contacted with a terminal exposed through the portion of the first housing.

According to an example embodiment, the external frame is electrically connected to the printed circuit board in the first housing through contact between the terminal and the contact portion, so that it can act as an antenna radiator.

The electronic devices may further include pins (e.g., the first pin 731b and the second pin 732b of FIG. 7). The pins may connect the external frame to be rotatable with respect to the first housing.

The contact portions may be spaced apart from the pins and extend along a part of the outer circumference of the pins.

According to an example embodiment, the electronic devices may be configured to rotate the external frame with respect to the first housing and the second housing through pin coupling. The contact portion extending along a portion of the outer circumference of the pin may maintain the connection between the contact portion and the terminal with the conductive portion of the external frame, based on the external frame being moved or while being moved.

According to an example embodiment, the terminal may move along the contact portions according to the rotation of the external frame.

According to an example embodiment, the contact between the contact portion and the terminal may be maintained according to the movement of the pin-coupled external frame.

The display area of the flexible display may include portions of a rollable portion of the flexible display that are visible through the portion of the first housing.

According to an example embodiment, a relatively wide screen may be provided using the rollable portion of the flexible display as a display area.

According to an example embodiment, the portion of the first housing may have a round shape corresponding to a rolled shape of the flexible display.

According to an example embodiment, an electronic device may further include a band (e.g., the accessory 1210 of FIG. 12). A band connected to the external frame may be further included.

According to an example embodiment, the electronic devices may provide a ring portion for coupling an accessory. The external frame may be used as the ring portion. Accessories such as a bands or a strap may increase the usability of the electronic device.

Since another accessory may be fastened, the electronic device is possible to represent a user's personality or improve the aesthetics of the electronic device.

According to an example embodiment, an electronic device (e.g., the electronic device 100 of FIG. 1A, the electronic device 400 of FIG. 4) may include: a first housing (e.g., the first housing 210 of FIG. 1A) and a second housing (e.g., the second housing 220 of FIG. 1A). The second housing may be configured to be movably coupled to the first housing. The electronic device may further include a flexible display (e.g., the display 140 of FIG. 1A). The flexible display may be configured to be partially rolled into the first housing according to the movement of the second housing. The flexible display may be at least partially disposed in the first housing and the second housing. The electronic device may further include an external frame (e.g., the external frame 430 of FIG. 4). The external frame may include connection portions (e.g., connection portions 431 and 432 of FIG. 4). The connection portions may be connected to both side surfaces of a portion of the first housing into which the flexible display is rolled. The external frame may include a frame part. The frame part may be disposed between the connection portions. The frame part may be spaced apart from the portion of the first housing. The external frame may at least partially surround a portion of the first housing facing the frame part and protect a bending area of the flexible display from impact applied to the frame part.

According to an example embodiment, the electronic device may include the frame part spaced apart from a portion of the first housing, thereby reducing damage to the flexible display due to external impact. It is possible to increase the durability of the electronic device by reducing a direct impact on the first housing surrounding the curved portion of the flexible display that is a vulnerable portion of the electronic device.

According to an example embodiment, electronic device may further include wireless communication circuitry (e.g., the wireless communication circuitry 611 of FIG. 6). The wireless communication circuitry may be configured to communicate with an external electronic device through a conductive portion (e.g., the first conductive portion 811, the second conductive portion 812 of FIG. 8A, the first conductive pattern 821, the second conductive pattern 822, or the second conductive pattern 1122 of FIG. 11B). The electronic device may further include an FPCB. The FPCB may be electrically connected to the wireless communication circuitry and the conductive portions. The conductive portion may be electrically connected to a terminal disposed at the portion of the first housing.

According to an example embodiment, the external frame may act as an antenna radiator by including a conductive portion. The external frame may be disposed outside the first housing to separate a physical distance between the antenna radiator and the display. Distortion of a signal transmitted and received through an antenna radiator separated from the display may be reduced.

According to an example embodiment, an external frame may include conductive portions spaced apart from each other from the non-conductive portion forming an outer surface. The conductive portions may be configured to act as an antenna radiator.

According to an example embodiment, an external frame may further include connection portions rotatably connected to a portion of the first housing.

According to an example embodiment, the conductive portions disposed on the external frame may act slit antennas or segmented antennas, and support multiple bands.

The effects that can be obtained from the present disclosure are not limited to those described above, and any other effects not mentioned herein will be clearly understood by those having ordinary skill in the art to which the present disclosure belongs, from the description.

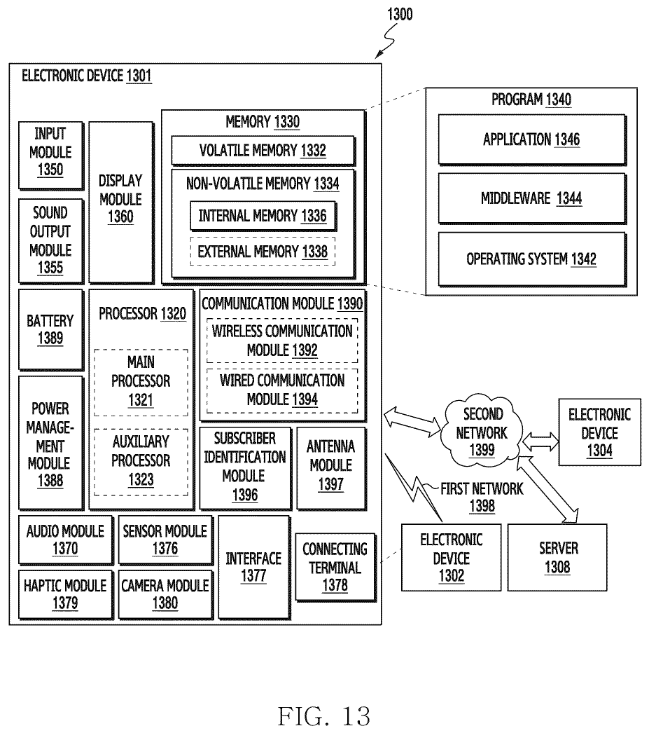

FIG. 13 is a block diagram illustrating an example electronic device 1301 in a network environment 1300 according to various embodiments.

Referring to FIG. 13, the electronic device 1301 in the network environment 1300 may communicate with an electronic device 1302 via a first network 1398 (e.g., a short-range wireless communication network), or at least one of an electronic device 1304 or a server 1308 via a second network 1399 (e.g., a long-range wireless communication network). According to an embodiment, the electronic device 1301 may communicate with the electronic device 1304 via the server 1308. According to an embodiment, the electronic device 1301 may include a processor 1320, memory 1330, an input module 1350, a sound output module 1355, a display module 1360, an audio module 1370, a sensor module 1376, an interface 1377, a connecting terminal 1378, a haptic module 1379, a camera module 1380, a power management module 1388, a battery 1389, a communication module 1390, a subscriber identification module (SIM) 1396, or an antenna module 1397. In various embodiments, at least one of the components (e.g., the connecting terminal 1378) may be omitted from the electronic device 1301, or one or more other components may be added in the electronic device 1301. In various embodiments, some of the components (e.g., the sensor module 1376, the camera module 1380, or the antenna module 1397) may be implemented as a single component (e.g., the display module 1360).

The processor 1320 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 1320 may execute, for example, software (e.g., a program 1340) to control at least one other component (e.g., a hardware or software component) of the electronic device 1301 coupled with the processor 1320, and may perform various data processing or computation. According to an embodiment, as at least part of the data processing or computation, the processor 1320 may store a command or data received from another component (e.g., the sensor module 1376 or the communication module 1390) in volatile memory 1332, process the command or the data stored in the volatile memory 1332, and store resulting data in non-volatile memory 1334. According to an embodiment, the processor 1320 may include a main processor 1321 (e.g., a central processing unit (CPU) or an application processor (AP)), or an auxiliary processor 1323 (e.g., a graphics processing unit (GPU), a neural processing unit (NPU), an image signal processor (ISP), a sensor hub processor, or a communication processor (CP)) that is operable independently from, or in conjunction with, the main processor 1321. For example, when the electronic device 1301 includes the main processor 1321 and the auxiliary processor 1323, the auxiliary processor 1323 may be adapted to consume less power than the main processor 1321, or to be specific to a specified function. The auxiliary processor 1323 may be implemented as separate from, or as part of the main processor 1321.

The auxiliary processor 1323 may control at least some of functions or states related to at least one component (e.g., the display module 1360, the sensor module 1376, or the communication module 1390) among the components of the electronic device 1301, instead of the main processor 1321 while the main processor 1321 is in an inactive (e.g., sleep) state, or together with the main processor 1321 while the main processor 1321 is in an active state (e.g., executing an application). According to an embodiment, the auxiliary processor 1323 (e.g., an image signal processor or a communication processor) may be implemented as part of another component (e.g., the camera module 1380 or the communication module 1390) functionally related to the auxiliary processor 1323. According to an embodiment, the auxiliary processor 1323 (e.g., the neural processing unit) may include a hardware structure specified for artificial intelligence model processing. An artificial intelligence model may be generated by machine learning. Such learning may be performed, e.g., by the electronic device 1301 where the artificial intelligence is performed or via a separate server (e.g., the server 1308). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 1330 may store various data used by at least one component (e.g., the processor 1320 or the sensor module 1376) of the electronic device 1301. The various data may include, for example, software (e.g., the program 1340) and input data or output data for a command related thereto. The memory 1330 may include the volatile memory 1332 or the non-volatile memory 1334.

The program 1340 may be stored in the memory 1330 as software, and may include, for example, an operating system (OS) 1342, middleware 1344, or an application 1346.

The input module 1350 may receive a command or data to be used by another component (e.g., the processor 1320) of the electronic device 1301, from the outside (e.g., a user) of the electronic device 1301. The input module 1350 may include, for example, a microphone, a mouse, a keyboard, a key (e.g., a button), or a digital pen (e.g., a stylus pen).

The sound output module 1355 may output sound signals to the outside of the electronic device 1301. The sound output module 1355 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 1360 may visually provide information to the outside (e.g., a user) of the electronic device 1301. The display module 1360 may include, for example, a display, a hologram device, or a projector and control circuitry to control a corresponding one of the display, hologram device, and projector. According to an embodiment, the display module 1360 may include a touch sensor adapted to detect a touch, or a pressure sensor adapted to measure the intensity of force incurred by the touch.

The audio module 1370 may convert a sound into an electrical signal and vice versa. According to an embodiment, the audio module 1370 may obtain the sound via the input module 1350, or output the sound via the sound output module 1355 or a headphone of an external electronic device (e.g., an electronic device 1302) directly (e.g., wiredly) or wirelessly coupled with the electronic device 1301.

The sensor module 1376 may detect an operational state (e.g., power or temperature) of the electronic device 1301 or an environmental state (e.g., a state of a user) external to the electronic device 1301, and then generate an electrical signal or data value corresponding to the detected state. According to an embodiment, the sensor module 1376 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1377 may support one or more specified protocols to be used for the electronic device 1301 to be coupled with the external electronic device (e.g., the electronic device 1302) directly (e.g., wiredly) or wirelessly. According to an embodiment, the interface 1377 may include, for example, a high definition multimedia interface (HDMI), a universal serial bus (USB) interface, a secure digital (SD) card interface, or an audio interface.

A connecting terminal 1378 may include a connector via which the electronic device 1301 may be physically connected with the external electronic device (e.g., the electronic device 1302). According to an embodiment, the connecting terminal 1378 may include, for example, an HDMI connector, a USB connector, a SD card connector, or an audio connector (e.g., a headphone connector).

The haptic module 1379 may convert an electrical signal into a mechanical stimulus (e.g., a vibration or a movement) or electrical stimulus which may be recognized by a user via his tactile sensation or kinesthetic sensation. According to an embodiment, the haptic module 1379 may include, for example, a motor, a piezoelectric element, or an electric stimulator.

The camera module 1380 may capture a still image or moving images. According to an embodiment, the camera module 1380 may include one or more lenses, image sensors, image signal processors, or flashes.

The power management module 1388 may manage power supplied to the electronic device 1301. According to an embodiment, the power management module 1388 may be implemented as at least part of, for example, a power management integrated circuit (PMIC).

The battery 1389 may supply power to at least one component of the electronic device 1301. According to an embodiment, the battery 1389 may include, for example, a primary cell which is not rechargeable, a secondary cell which is rechargeable, or a fuel cell.

The communication module 1390 may support establishing a direct (e.g., wired) communication channel or a wireless communication channel between the electronic device 1301 and the external electronic device (e.g., the electronic device 1302, the electronic device 1304, or the server 1308) and performing communication via the established communication channel. The communication module 1390 may include one or more communication processors that are operable independently from the processor 1320 (e.g., the application processor (AP)) and supports a direct (e.g., wired) communication or a wireless communication. According to an embodiment, the communication module 1390 may include a wireless communication module 1392 (e.g., a cellular communication module, a short-range wireless communication module, or a global navigation satellite system (GNSS) communication module) or a wired communication module 1394 (e.g., a local area network (LAN) communication module or a power line communication (PLC) module). A corresponding one of these communication modules may communicate with the external electronic device via the first network 1398 (e.g., a short-range communication network, such as Bluetooth™, wireless-fidelity (Wi-Fi) direct, or infrared data association (IrDA)) or the second network 1399 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1392 may identify and authenticate the electronic device 1301 in a communication network, such as the first network 1398 or the second network 1399, using subscriber information (e.g., international mobile subscriber identity (IMSI)) stored in the subscriber identification module 1396.

The wireless communication module 1392 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1392 may support a high-frequency band (e.g., the mm Wave band) to achieve, e.g., a high data transmission rate. The wireless communication module 1392 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 1392 may support various requirements specified in the electronic device 1301, an external electronic device (e.g., the electronic device 1304), or a network system (e.g., the second network 1399). According to an embodiment, the wireless communication module 1392 may support a peak data rate (e.g., 20 Gbps or more) for implementing cMBB, loss coverage (e.g., 1364 dB or less) for implementing mMTC, or U-plane latency (e.g., 0.5 ms or less for each of downlink (DL) and uplink (UL), or a round trip of 13 ms or less) for implementing URLLC.

The antenna module 1397 may transmit or receive a signal or power to or from the outside (e.g., the external electronic device) of the electronic device 1301. According to an embodiment, the antenna module 1397 may include an antenna including a radiating element including a conductive material or a conductive pattern formed in or on a substrate (e.g., a printed circuit board (PCB)). According to an embodiment, the antenna module 1397 may include a plurality of antennas (e.g., array antennas). In such a case, at least one antenna appropriate for a communication scheme used in the communication network, such as the first network 1398 or the second network 1399, may be selected, for example, by the communication module 1390 (e.g., the wireless communication module 1392) from the plurality of antennas. The signal or the power may then be transmitted or received between the communication module 1390 and the external electronic device via the selected at least one antenna. According to an embodiment, another component (e.g., a radio frequency integrated circuit (RFIC)) other than the radiating element may be additionally formed as part of the antenna module 1397.

According to various embodiments, the antenna module 1397 may form a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1301 and the external electronic device 1304 via the server 1308 coupled with the second network 1399. Each of the electronic devices 1302 or 1304 may be a device of a same type as, or a different type, from the electronic device 1301. According to an embodiment, all or some of operations to be executed at the electronic device 1301 may be executed at one or more of the external electronic devices 1302, 1304, or 1308. For example, if the electronic device 1301 should perform a function or a service automatically, or in response to a request from a user or another device, the electronic device 1301, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1301. The electronic device 1301 may provide the outcome, with or without further processing of the outcome, as at least part of a reply to the request. To that end, a cloud computing, distributed computing, mobile edge computing (MEC), or client-server computing technology may be used, for example. The electronic device 1301 may provide ultra low-latency services using, e.g., distributed computing or mobile edge computing. In an embodiment, the external electronic device 1304 may include an internet-of-things (IoT) device. The server 1308 may be an intelligent server using machine learning and/or a neural network. According to an embodiment, the external electronic device 1304 or the server 1308 may be included in the second network 1399. The electronic device 1301 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

One or more embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to one or more embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to one or more embodiments, each component (e.g., a module or a program) of the above-described components may include a single entity or multiple entities, and some of the multiple entities may be separately disposed in different components. According to one or more embodiments, one or more of the above-described components may be omitted, or one or more other components may be added. Alternatively or additionally, a plurality of components (e.g., modules or programs) may be integrated into a single component. In such a case, according to one or more embodiments, the integrated component may still perform one or more functions of each of the plurality of components in the same or similar manner as they are performed by a corresponding one of the plurality of components before the integration. According to one or more embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

No claim element is to be construed under the provisions of 35 U.S.C. § 112, sixth paragraph, unless the element is expressly recited using the phrase “means for” or “means.”

What is claimed is:

1. An electronic device comprising:
a first housing;
a second housing configured to be movably coupled to the first housing;
a flexible display configured to move to change a visible area according to a movement of the second housing; and
an external frame connected to a portion of the first housing and configured to protect a bending portion of the flexible display from external impact.

2. The electronic device according to claim 1, wherein the portion of the first housing is a portion of the first housing positioned next to the bending portion.

3. The electronic device according to claim 1, further comprising:
wireless communication circuitry configured to wirelessly communicate with an external electronic device through a conductive portion of the external frame; and
a flexible printed circuit board (FPCB) electrically connected to the wireless communication circuitry and the conductive portion.

4. The electronic device according to claim 2, wherein the conductive portion is electrically connected to a terminal disposed at the portion of the first housing.

5. The electronic device according to claim 4, wherein the terminal is a movable terminal comprising a C-clip or pogo pin.

6. The electronic device of claim 1, wherein the external frame includes:
a first conductive pattern extending from one end of the external frame to another end of the external frame; and
a second conductive pattern spaced apart from the first conductive pattern, the second conductive pattern being parallel to the first conductive pattern;
wherein each of the first conductive pattern and the second conductive pattern is configured to act as an antenna radiator.

7. The electronic device according to claim 6, further comprising at least one wireless communication circuitry configured to communicate with an external electronic device using a first frequency band through the first conductive pattern and communicate with an external electronic device using a second frequency band through the second conductive pattern.

8. The electronic device of claim 1, wherein the external frame includes a non-conductive portion forming an outer surface of the external frame and conductive portions spaced apart from each other, and
wherein the conductive portions are configured to act as antenna radiators.

9. The electronic device of claim 1, wherein the external frame further includes a connection portion rotatably connected to the portion of the first housing.

10. The electronic device according to claim 9, wherein an angle between the external frame and the first housing varies in a range of 90 degrees to 180 degrees.

11. The electronic device of claim 1, wherein the external frame further includes a contact portion connected to a conductive portion of the external frame and configured to contact a terminal exposed through the portion of the first housing.

12. The electronic device according to claim 11, further comprising a pin connecting the external frame to be rotatable with respect to the first housing,
wherein the contact portion is spaced apart from the pin and extends along a part of an outer circumference of the pin.

13. The electronic device according to claim 12, wherein the terminal is configured to move along the contact portion according to the rotation of the external frame.

14. The electronic device of claim 1, wherein a display area of the flexible display includes a portion of a rolled portion of the flexible display that is visible through the portion of the first housing.

15. The electronic device of claim 1, wherein the portion of the first housing has a round shape corresponding to a rolled shape of the flexible display.

16. The electronic device of claim 1, further comprising a band connected to the external frame.

17. An electronic device comprising:
a first housing;
a second housing movably coupled to the first housing;
a flexible display at least partially disposed in the first housing and the second housing and configured to be partially rolled into the first housing; and
an external frame including connection portions connected to both side surfaces of a portion of the first housing into which the flexible display is configured to be rolled and a frame part disposed between the connection portions and spaced apart from the portion of the first housing;
wherein the external frame at least partially surrounds a portion of the first housing facing the frame part and is configured to protect a bending portion of the flexible display from impact applied to the frame part.

18. The electronic device according to claim 17, wherein the external frame further includes wireless communication circuitry configured to communicate with an external electronic device through a conductive portion of the external frame configured to act as an antenna radiator and a flexible printed circuit board (FPCB) electrically connected to the wireless communication circuitry and the conductive portion,
wherein the conductive portion is electrically connected to a terminal disposed at the portion of the housing.

19. The electronic device according to claim 17, wherein the external frame includes a non-conductive portion forming an outer surface and conductive portions spaced apart from each other,
wherein the conductive portions are configured to act as antenna radiators.

20. The electronic device according to claim 17, wherein the external frame further includes a connection portion rotatably connected to the portion of the first housing.
